(19) United States
(12) Patent Application Publication
(10) Pub. No.: US 2011/0134707 A1
(43) Pub. Date: Jun. 9, 2011

(54) BLOCK ISOLATION CONTROL CIRCUIT

(76) Inventor: Saeng Hwan KIM, Suwon-si (KR)

(21) Appl. No.: 13/024,169

(22) Filed: Feb. 9, 2011

Related U.S. Application Data
(63) Continuation-in-part of application No. 12/070,952, filed on Feb. 22, 2008.

(30) Foreign Application Priority Data
Nov. 2, 2007 (KR) 10-2007-0111521

(51) Int. Cl. G11C 29/44; G11C 7/10

(52) U.S. Cl. 365/189.05; 365/200; 365/189.11

(57) ABSTRACT

A block isolation control circuit includes: a control signal generation unit configured to generate a control signal which is disabled when a defect occurs in a cell block and it is necessary to replace a defective cell block with a redundant cell block, or when the cell block is not selected in a test mode; and at least one switch element connected between the cell block and a bit line sense amplifier, wherein the switch element isolates the cell block from the bit line sense amplifier when the control signal is disabled.

### CROSS-REFERENCES TO RELATED APPLICATIONS

This is a continuation-in-part application of U.S. application Ser. No. 12/070,952 filed Feb. 22, 2008, which claims the priority benefit under USC 119 of KR10-2007-0111521 filed Nov. 2, 2007, the entire respective disclosures of which are incorporated herein by reference.

### BACKGROUND

FIG. 1 illustrates a block diagram of a conventional DRAM cell, and FIG. 2 illustrates a circuit diagram of a conventional bit line sense amplifier.

As illustrated in FIG. 1, a cell block A is connected to bit line sense amplifiers BLSA0 to BLSA3 by NMOS transistors which are turned on in response to a down control signal BIS_DN1 and an up control signal BIS_UP2, and a cell block B is connected to bit line sense amplifiers BLSA2 to BLSA5 by NMOS transistors which are turned on in response to a down control signal BIS_DN2 and an up control signal BIS_UP3. The bit line sense amplifiers BLSA0 and BLSA1 are connected to an adjacent cell block (not shown) by NMOS transistors which are turned on in response to an up control signal BIS_UP1, and the bit line sense amplifiers BLSA4 and BLSA5 are connected to an adjacent cell block (not shown) by NMOS transistors which are turned on in response to a down control signal BIS_DN3. The bit line sense amplifiers BLSA0 to BLSA5 are configured as illustrated in FIG. 2. That is, each of the bit line sense amplifiers BLSA0 to BLSA5 includes a cross-coupled latch which senses and amplifies voltages of a bit line pair BL and BLb during an active operation, and NMOS transistors which supply a bit line precharge voltage VBLP during a precharge operation.

FIG. 3 illustrates a circuit diagram of a control signal generation unit which generates the up control signals BIS_UP1 to BIS_UP3 and the down control signals BIS_DN1 to BIS_DN3. As illustrated in FIG. 3, a control signal generation unit (BIS_B Control) inverts and buffers a bank address A ADD and a bank address B ADD, and generates the second up control signal BIS_UP2 and the second down control signal BIS_DN2. A control signal generation unit (BIS_C Control) inverts and buffers a bank address C ADD and the bank address B ADD, and generates the third up control signal BIS_UP3 and the third down control signal BIS_DN3.

When only the cell block B is selected, the control signal generation unit receives the bank address B ADD of a high level and the bank address A ADD of a low level, and generates the second up control signal BIS_UP2 of a low level and the second down control signal BIS_DN2 of a high level. In addition, when only the cell B is selected, the control signal generation unit receives the bank address C ADD of a low level and the bank address B ADD of a high level, and generates the third up control signal BIS_UP3 of a high level and the third down control signal BIS_DN3 of a low level.

As such, when only the cell block B is selected, the second up control signal BIS_UP2 of the low level is generated to isolate the cell block A from the bit line sense amplifiers BLSA2 and BLSA3, and the second down control signal BIS_DN2 of the high level connects the cell block B to the bit line sense amplifiers BLSA2 and the BLSA3. In addition, the third up control signal BIS_UP3 of the high level connects the cell block B to the bit line sense amplifiers BLSA4 and BLSA5, and the third down control signal BIS_DN3 of the low level isolates the adjacent cell block (not shown) from the bit line sense amplifiers BLSA4 and BLSA5. In this manner, the selected cell block B is connected to the bit line sense amplifiers BLSA2 to BLSA5 and is isolated from the adjacent cell block (not shown) including the cell block A. The selected cell block B is isolated from other cell blocks and is connected to the bit line sense amplifiers BLSA2 to BLSA5 in order to reduce loading by isolating the adjacent cell block from the bit lines.

Meanwhile, the unselected cell block A and the adjacent cell block (not shown) are connected to the bit line sense amplifiers BLSA0 and BLSA1 and the bit line sense amplifiers BLSA4 and BLSA5, respectively, and are supplied with a bit line precharge voltage VBLP.

When a defect occurs in the cell block as illustrated in FIG. 4, for example, when a bit line or a word line is physically shorted, the cell block is replaced with a redundant cell block by a repair circuit. However, the cell block replaced with the redundant cell block is continuously connected to the bit line sense amplifier, and the corresponding cell block is continuously precharged to the bit line precharge voltage VBLP, causing power consumption.

### SUMMARY

Various embodiments of the present disclosure are directed to a block isolation control circuit which can reduce power consumption by interrupting the supply of a bit line precharge voltage to a bit line of a cell block in which a defect such as a physical short occurs.

In one embodiment, a block isolation control circuit includes: a control signal generation unit configured to generate a control signal which is disabled when a defect occurs in a cell block and it is necessary to replace a defective cell block with a redundant cell block, or when the cell block is not selected in a test mode; and at least one switch element connected between the cell block and a bit line sense amplifier, wherein the switch element isolates the cell block from the bit line sense amplifier when the control signal is disabled.

In another embodiment, a block isolation control circuit includes: a first control signal generation unit configured to generate a first control signal which disabled when a defect occurs in a first cell block and it is necessary to replace the first cell block with a first redundant cell block, or when a second cell block sharing a first bit line sense amplifier is selected, and to generate the first control signal which is disabled when the first cell block is not selected in a test mode; a first switch element connected between the first cell block and the first bit line sense amplifier and configured to isolate the first cell block from the first bit line sense amplifier when the first control signal is disabled; a second control signal generation unit configured to generate a second control signal which disabled when a defect occurs in a second cell block and it is necessary to replace the second cell block with a second redundant cell block, or when the first cell block is selected, and to generate the second control signal which is disabled when the second cell block is not selected in the test mode; and a second switch element connected between the second cell block and the first bit line sense amplifier and configured to isolate the second cell block from the first bit line sense amplifier when the second control signal is disabled.

In another embodiment, a block isolation control circuit includes: a block repair selector configured to generate a repair detection signal which is enabled when a defect occurs in a cell block, the cell block is replaced with a first redundant cell block, and the cell block is selected; a control signal generation unit configured to generate a control signal which is disabled when a defect occurs in the first redundant cell block and it is necessary to replace the first redundant cell block with a second redundant cell block, or when the first redundant cell block is not selected in a test mode; and at least one switch element connected between the first redundant cell block and a bit line sense amplifier, wherein the switch element isolates the first redundant cell block from the bit line sense amplifier when the control signal is disabled.

### BRIEF DESCRIPTION OF THE DRAWINGS

FIG. 1 illustrates a block diagram of a conventional DRAM cell.

FIG. 2 illustrates a circuit diagram of a conventional bit line sense amplifier.

FIG. 3 illustrates a circuit diagram of a conventional control signal generation unit.

FIG. 4 illustrates a case in which a physical short occurs in a conventional DRAM cell.

FIG. 5 illustrates a block diagram of a block repair apparatus of a DRAM cell according to an exemplary embodiment of the present invention.

FIGS. 6 to 8 illustrate a block diagram of a block isolation control circuit according to an exemplary embodiment of the present invention.

FIGS. 9A and 9B illustrate the configuration and operation of a block repair fuse unit according to an exemplary embodiment present invention.

FIG. 10 illustrates a circuit diagram of a block repair selector according to an exemplary embodiment of the present invention.

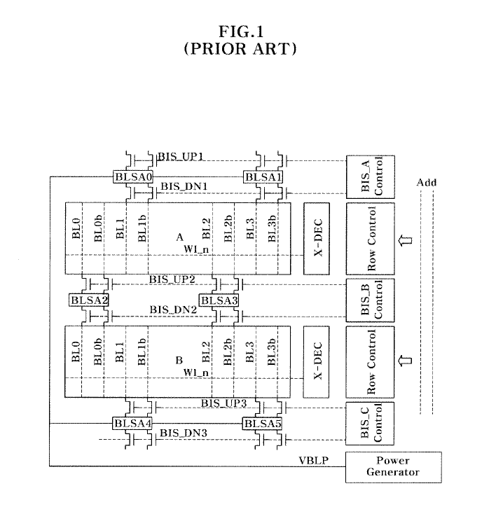

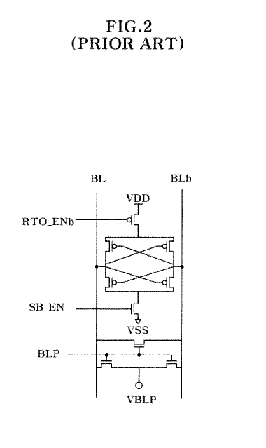

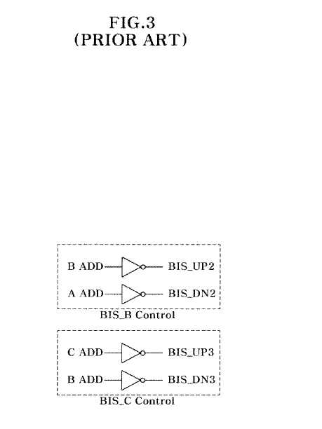

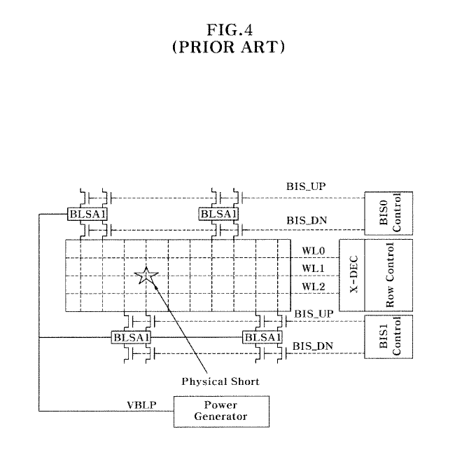

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

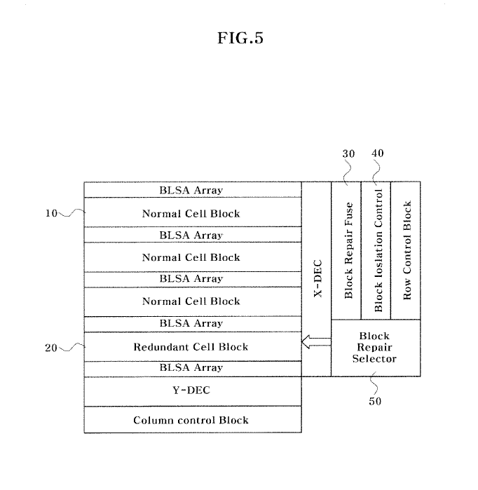

FIG. 5 illustrates a block diagram of a block repair apparatus of a DRAM cell according to an exemplary embodiment of the present invention.

Referring to FIG. 5, the block repair apparatus according to the exemplary embodiment of the present invention includes a redundant cell block 20, a block repair fuse unit 30, a control signal generation unit 40, and a block repair selector 50. The redundant cell block 20 replaces a defective cell block when an electrical short or a cell defect occurs in a specific block among a plurality of cell blocks 10. The block repair fuse unit 30 outputs a block repair signal of the plurality of cell blocks 10. The control signal generation unit 40 outputs a control signal for activating the plurality of cell blocks 10 or electrically isolating the defective cell block among the plurality of cell blocks 10, in response to the block repair signal. The block repair selector 50 outputs a block repair selection signal for replacing the defective cell block with another cell block in response to a cell block address signal.

In addition, the block repair apparatus includes a sense amplifier array, an X-decoder, a Y-decoder block, a row control block, and a column control block. The sense amplifier array senses a bit line used in a conventional DRAM. The X-decoder and Y-decoder blocks select a word line and a bit line, respectively. The row control block and the column control block control rows and columns, respectively.

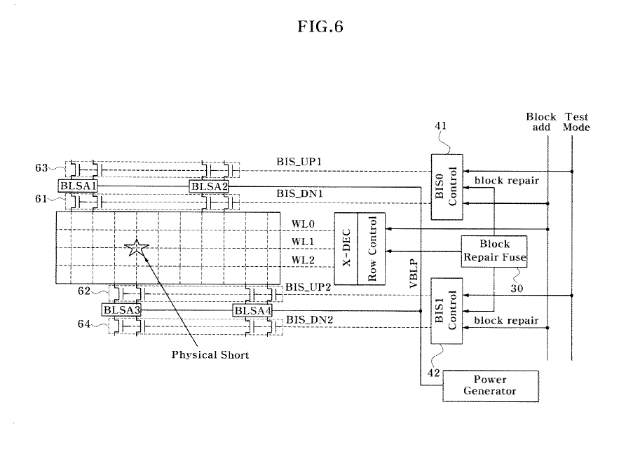

FIGS. 6 to 8 illustrate a block diagram of a block isolation control circuit according to an exemplary embodiment of the present invention.

Referring to FIG. 6, the block isolation control circuit according to the exemplary embodiment of the present invention includes a block repair fuse unit 30, a first control signal generation unit 41, a second control signal generation unit 42, a first switch unit 61, and a second switch unit 62. The block repair fuse unit 30 generates a block repair signal which is enabled when a defect occurs in a cell block, for example, when a bit line or a word line is physically shorted. The first control signal generation unit 41 receives the block repair signal, a block address, and a test mode signal, and generates a first up control signal BIS_UP1 and a first down control signal BIS_DN1. The second control signal generation unit 42 receives the block repair signal, the block address, and the test mode signal, and generates a second up control signal BIS_UP2 and a second down control signal BIS_DN2. The first switch unit 61 includes a plurality of NMOS transistors connected between bit line sense amplifiers BLSA1 and BLSA2 and a cell block, and controls the connection of the cell block and the bit line sense amplifiers BLSA1 and BLSA2 in response to the first down control signal BIS_DN1. The second switch unit 62 includes a plurality of NMOS transistors connected between bit line sense amplifiers BLSA3 and BLSA4 and the cell block, and controls the connection of the cell block and the bit line sense amplifiers BLSA3 and BLSA4 in response to the second up control signal BIS_UP2. The third switch unit 63 includes a plurality of NMOS transistors connected between the bit line sense amplifiers BLSA1 and BLSA2 and an upper adjacent cell block (not shown), and controls the connection of the upper adjacent cell block (not shown) and the bit line sense amplifiers BLSA1 and BLSA2 in response to the first up control signal BIS_UP1. The fourth switch unit 64 includes a plurality of NMOS transistors connected between the bit line sense amplifiers BLSA3 and BLSA4 and a lower adjacent cell block (not shown), and controls the connection of the lower adjacent cell block (not shown) and the bit line sense amplifiers BLSA3 and BLSA4 in response to the second down control signal BIS_DN2.

When a defect occurs in the cell block, the block isolation control circuit turns off all the NMOS transistors included in the first switch unit 61 and the second switch unit 62 by disabling the first down control signal BIS_DN1 and the second up control signal BIS_UP2 to a low level. As a result, the block isolation control circuit interrupts the supply of the bit line precharge voltage VBLP to the cell block. Meanwhile, when the cell block is selected, the first down control signal BIS_DN1 and the second up control signal BIS_UP2 are enabled to a high level, and thus, the cell block is connected to the bit line sense amplifiers BLSA1 to BLSA4. In addition, the first up control signal BIS_UP1 and the second down control signal BIS_DN2 are enabled to a low level, and thus, all the NMOS transistors included in the third switch unit 63 and the fourth switch unit 64 are turned off. As a result, the bit line sense amplifiers are isolated from the upper adjacent cell block (not shown) and the lower adjacent cell block (not shown).

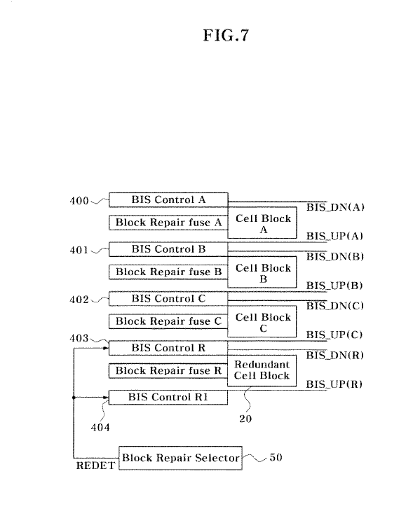

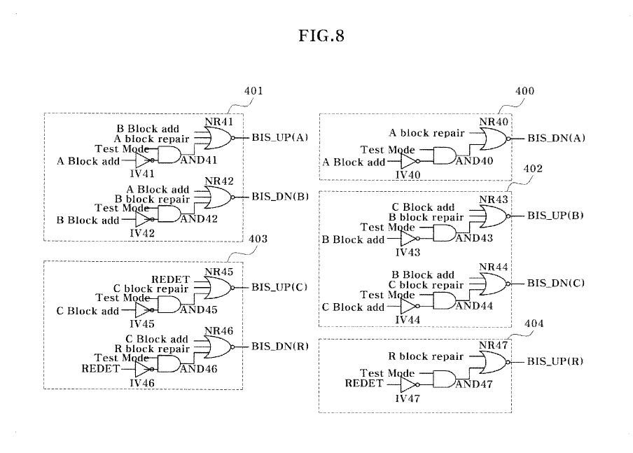

A specific implementation of the block isolation control circuit according to the exemplary embodiment of the present invention is illustrated in FIGS. 7 and 8.

Referring to FIG. 7, the block isolation control circuit according to the exemplary embodiment of the present invention includes a first control signal generation unit 400, a second control signal generation unit 401, a third control signal generation unit 402, a fourth control signal generation unit 403, a fifth control signal generation unit 404, and a block repair selector 50.

The first control signal generation unit 400 generates a first down control signal BIS_DN(A) which controls a switch unit (not shown) connected between a cell block A and a first upper bit line sense amplifier (not shown). When the first down control signal BIS_DN(A) is at a high level, an NMOS transistor included in the first switch unit (not shown) is turned on so that the cell block A is connected to the first upper bit line sense amplifier (not shown). Meanwhile, when the first down control signal BIS_DN(A) is at a low level, the NMOS transistor included in the first switch unit (not shown) is turned off so that the cell block A is isolated from the first upper bit line sense amplifier (not shown).

More specifically, as illustrated in FIG. 8, the first control signal generation unit 400 includes an AND gate AND40 and a NOR gate NR40. The AND gate AND40 performs an AND operation on a test mode signal and an inversion signal of a first block address (A Block add) which is enabled to a high level when the cell block A is selected. The NOR gate NR40 performs a NOR operation on an output signal of the AND gate AND40 and a first block repair signal (A block repair) which is inputted with a high level when the cell block A is repaired, and generates the first down control signal BIS_DN(A).

The first control signal generation unit 400 generates the first down control signal BIS_DN(A) which is disabled to a low level when a detect occurs in the cell block A and the first block repair signal is at a high level. In addition, the first control signal generation unit 400 generates the first down control signal BIS_DN(A) which is disabled to a low level, even when the first block address of a low level is inputted because the cell block A is not selected in such a state the test mode signal is at a high level. The test mode signal is a signal which is enabled to a high level in order to enter a test mode for electrically isolating the cell blocks. When the test mode signal is at a high level, the selected cell blocks are connected to the bit line sense amplifiers, and the unselected cell blocks are isolated from the bit line sense amplifiers.

The second control signal generation unit 401 generates a first up control signal BIS_UP(A) which controls a second switch unit (not shown) connected between the cell block A and a first lower bit line sense amplifier (not shown), and a second down control signal BIS_DN(B) which controls a third switch unit (not shown) connected between a cell block B and a second upper bit line sense amplifier (not shown). More specifically, as illustrated in FIG. 8, the second control signal generation unit 401 includes an AND gate AND41, a NOR gate NR41, an AND gate AND42, and a NOR gate NR42. The AND gate AND41 performs an AND operation on the test mode signal and the inversion signal of the first block address (A Block add). The NOR gate NR41 performs a NOR operation on a second block address (B Block add) which is enabled to a high level when the cell block B is selected, the first block repair signal (A block repair) which is inputted with a high level when the cell block A is repaired, and an output signal of the AND gate AND41, and generates the first up control signal BIS_UP(A). The AND gate AND42 performs an AND operation on the test mode signal and an inversion signal of the second block address (B Block add). The NOR gate NR42 performs a NOR operation on the first block address (A Block add), a second block repair signal (B block repair) which is inputted with a high level when the cell block B is repaired, and an output signal of the AND gate AND42, and generates the second down control signal BIS_DN(B).

The second control signal generation unit 401 generates the first up control signal BIS_UP(A) which is disabled to a low level to turn off the second switch unit (not shown), when a defect occurs in the cell block A and the first block repair signal of a high level is inputted, or when the cell block B is selected and the second block address of a high level is inputted. In addition, the second control signal generation unit 401 generates the second down control signal BIS_DN(B) which is disabled to a low level to turn off the third switch unit (not shown), when a defect occurs in the cell block B and the second block repair signal of a high level is inputted, or when the cell block A is selected and the first block address of a high level is inputted. Meanwhile, the second control signal generation unit 401 generates the first up control signal BIS_UP(A) which is disabled to a low level when the first block address of a low level is inputted because the cell block A is not selected in such a state the test mode signal is at a high level, and generates the second down control signal BIS_DN(B) which is disabled to a low level when the second block address of a low level is inputted because the cell block B is not selected.

Since the configuration of the third control signal generation unit 402 and the fourth control signal generation unit 403 is substantially similar to that of the second control signal generation unit 401, and the configuration of the fifth control signal generation unit 404 is substantially similar to that of the first control signal generation unit 400, detailed description thereof will be omitted. Hereinafter, the operations of the third control signal generation unit 402, the fourth control signal generation unit 403, and the fifth control signal generation unit 404 will be described.

The third control signal generation unit 402 generates the second up control signal BIS_UP(B) which is disabled to a low level when a defect occurs in the cell block B and the second block repair signal of a high level is inputted, or when the cell block C is selected and the third block address (C Block add) of a high level is inputted. In addition, the third control signal generation unit 402 generates the third down control signal BIS_DN(C) which is disabled to a low level when a defect occurs in the cell block C and a third block repair signal (C block repair) of a high level is inputted, or when the cell block B is selected and the second block address of a high level is inputted. Meanwhile, the third control signal generation unit 402 generates the second up control signal BIS_UP(B) which is disabled to a low level when the second block address of a low level is inputted because the cell block B is not selected in such a state that the test mode signal is at a high level, and generates the third down control signal which is disabled to a low level when the third block address of a low level is inputted because the cell block C is not selected.

The fourth control signal generation unit 403 generates the third up control signal BIS_UP(C) which is disabled to a low level when a defect occurs in the cell block C and the third block repair signal (C block repair) of a high level is inputted, or when the redundant cell block is selected and a repair detection signal REDET of a high level is inputted. In addition, the fourth control signal generation unit 403 generates the fourth down control signal BIS_DN(R) which is disabled to a low level when a defect occurs in the redundant cell block occurs and the fourth block repair signal (R block repair) of a high level is inputted, or when the cell block C is selected and the third block address of a high level is inputted. Meanwhile, the fourth control signal generation unit 403 generates the third up control signal BIS_UP(C) which is disabled to a low level when the third block address of a low level is inputted because the cell block C is not selected in such a state that the test mode signal is at a high level, and generates the fourth down control signal BIS_DN(R) which is disabled to a low level when the repair detection signal REDET of a low level is inputted because the redundant cell block is not selected. The case in which the redundant cell block is selected refers to a case in which a defect occurs in any one of the cell blocks A, B and C, the defective cell block is replaced with the redundant cell block, and the repair detection signal REDET of a low level is generated from the block repair selector 50. The configuration and operation of the block repair selector 50 will be described later.

The fifth control signal generation unit 404 generates the fourth up control signal BIS_UP(R) which is disabled to a low level when a defect occurs in the redundant cell block and the fourth block repair signal (R block repair) of a high level is inputted. In addition, the fifth control signal generation unit 404 generates the fourth up control signal BIS_UP(R) which is disabled to a low level when the repair detection signal REDET of a low level is inputted because the redundant cell block is not selected in such a state that the test mode signal is at a high level.

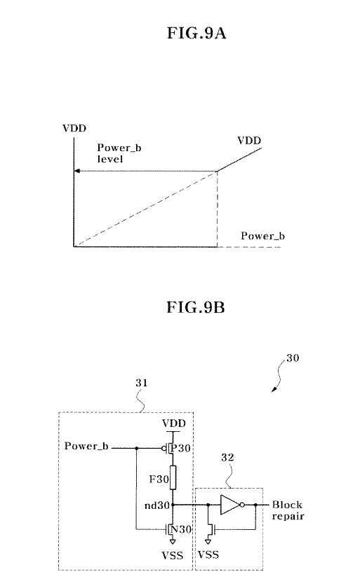

FIGS. 9A and 9B illustrate the configuration and operation of the block repair fuse unit according to an exemplary embodiment present invention.

Referring to FIG. 9A, a level of a power up signal Power_b inputted to the block repair fuse unit 30 according to the exemplary embodiment of the present invention rises along an external voltage VDD in a power up period until before the external voltage VDD reaches a target level (Power_b level), and changes to a low level after the external voltage VDD reaches the target level (Power_b level).

Referring to FIG. 9B, the block repair fuse unit 30 according to the exemplary embodiment of the present invention includes a PMOS transistor P30, a fuse F30, an NMOS transistor N30, and a latch 32. The PMOS transistor P30 and the fuse F30 are connected in series between an external voltage (VDD) terminal and a node nd30. The NMOS transistor N30 is connected between the node nd30 and a ground voltage (VSS) terminal. The latch 32 latches a signal of the node nd30. The PMOS transistor P30 operates as a pull up element which pulls up the node nd30 in response to the power up signal Power_b, and the NMOS transistor N30 operates as a pull down element which pulls down the node nd30 in response to the power up signal Power_b. In addition, the latch 32 latches the signal of the node nd30 when the node nd30 is pulled down, and maintains the block repair signal at a high level.

When a defect does not occur in the cell block, the fuse F30 is not cut and thus the block repair fuse unit 30 generates the block repair signal of a low level. When a defect occurs in the cell block, the fuse F30 is cut and thus the block repair fuse unit 30 generates the block repair signal of a high level.

When the address of the cell block is an address of a defective cell block, the defective cell block is replaced with the redundant cell block 20 by using the block isolation control unit 40. Specifically, replacing the defective cell block with the redundant cell block is performed in such a manner that the block isolation control unit 40 supplies electricity to the redundant cell block, instead of the defective cell block, in response to the output signal of the block repair selector 50.

Although the block repair fuse unit 30 implemented with a single circuit is illustrated, it may be provided at each cell block to generate the block repair signal according to whether or not a defect occurs in each cell block.

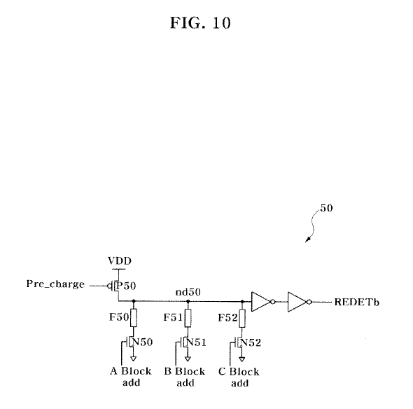

FIG. 10 illustrates a circuit diagram of the block repair selector 50 according to an exemplary embodiment of the present invention.

Referring to FIG. 10, the block repair selector 50 according to the exemplary embodiment of the present invention includes a PMOS transistor P50, first to third fuses F50 to F52, and NMOS transistors N50 to N52. The PMOS transistor P50 operates as a pull up element which pulls up a node nd50 in response to a precharge signal Pre_charge of a low level. The first to third fuses F50 to F52 are connected to the node nd50. The NMOS transistors N50 to N52 are connected in series to the first to third fuses F50 to F52 and are turned on in response to the first to third block addresses (A Block add, B Block add, C Block add).

The operation of the block repair selector 50 will be described below. When a defect occurs in the cell block B and the cell block B is replaced with the redundant cell, the first and third fuses F50 and F52 are cut. In such a state, when the cell block B is selected and an inverted second block address (B Block addb) of a high level is inputted, the NMOS transistor N51 is turned on so that the node nd50 is pull down to a low level. Therefore, when the cell block B replaced with the redundant cell is selected, the block repair selector 50 generates an inverted repair detection signal REDETb of a low level. When the inverted repair detection signal REDETb has a low level, the repair detection signal REDET has a high level and it means that the redundant cell block is selected.

The operation of the block isolation control circuit will be described below. Specifically, a case in which a defect occurs in the cell block B and the defective cell block B is replaced with the redundant cell will be described for exemplary purposes.

When a defect occurs in the cell block B and the cell block B is selected in such a state that the cell block B is replaced with the redundant cell block, the block repair selector 50 generates the inverted repair detection signal REDETb of a low level. At this time, the block repair fuse unit 30 generates the second block repair signal of a high level by a fuse which is cut when a defect occurs in the cell block B.

Due to the repair detection signal REDET of a high level, the fourth control signal generation unit 403 generates the fourth down control signal BIS_DN(R) of a high level, and fifth control signal generation unit 404 generates the fourth up control signal BIS_UP(R) of a high level. Thus, the switches (not shown) connected between the redundant cell block and the bit line sense amplifiers are turned on, so that the redundant cell block and the bit line sense amplifiers are connected together.

In addition, due to the second block repair signal of a high level, the second control signal generation unit 401 generates the second down control signal BIS_DN(B) of a low level, and the third control signal generation unit 402 generates the second up control signal BIS_UP(B) of a low level. Therefore, the defective cell block B is electrically isolated from the bit line sense amplifiers.

As described above, when the defective cell block is replaced with the redundant cell block, the block isolation control circuit electrically isolates the detective cell block from the bit line sense amplifiers, thereby preventing unnecessary power consumption.

While the present invention has been described with respect to examples and exemplary embodiments, it will be apparent to those skilled in the art that various changes and modifications may be made without departing from the spirit and scope of the disclosure and the following claims. For example, elements and/or features of different examples and illustrative embodiments may be combined with each other and/or substituted for each other within the scope of this disclosure and appended claims.

What is claimed is:

1. A block isolation control circuit, comprising:
a control signal generation unit configured to generate a control signal which is disabled when a defect occurs in a cell block and it is necessary to replace a defective cell block with a redundant cell block, or when the cell block is not selected in a test mode; and
at least one switch element connected between the cell block and a bit line sense amplifier,
wherein the switch element isolates the cell block from the bit to line sense amplifier when the control signal is disabled.

2. The block isolation control circuit of claim 1, wherein the control signal generation unit comprises:
a first logic element configured to perform a logic operation on a test mode signal for entry into the test mode and an inversion signal of a block address signal which is enabled when the cell block is selected; and
a second logic element configured to perform a logic operation on an output signal of the first logic element and a block repair signal which is enabled when the defect occurs in the cell block.

3. The block isolation control circuit of claim 1, further comprising a block repair fuse unit configured to generate the block repair signal which is enabled when the defect occurs in the cell block.

4. The block isolation control circuit of claim 3, wherein the block repair fuse unit comprises:
a pull up element configured to pull up an output node in response to a power-up signal;
a pull down element configured to pull down the output node in response to the power-up signal;
a fuse connected between the pull up element and the output node; and
a latch unit configured to latch a signal of the output node.

5. The block isolation control circuit of claim 4, wherein the fuse is cut when the defect occurs in the cell block.

6. A block isolation control circuit, comprising:
a first control signal generation unit configured to generate a first control signal which disabled when a defect occurs in a first cell block and it is necessary to replace the first cell block with a first redundant cell block, or when a second cell block sharing a first bit line sense amplifier is selected, and to generate the first control signal which is disabled when the first cell block is not selected in a test mode;
a first switch element connected between the first cell block and the first bit line sense amplifier and configured to isolate the first cell block from the first bit line sense amplifier when the first control signal is disabled;
a second control signal generation unit configured to generate a second control signal which disabled when a defect occurs in a second cell block and it is necessary to replace the second cell block with a second redundant cell block, or when the first cell block is selected, and to generate the second control signal which is disabled when the second cell block is not selected in the test mode; and
a second switch element connected between the second cell block and the first bit line sense amplifier and configured to isolate the second cell block from the first bit line sense amplifier when the second control signal is disabled.

7. The block isolation control circuit of claim 6, wherein the first control signal generation unit comprises:
a first logic element configured to perform a logic operation on a test mode signal for entry into the test mode and an inversion signal of a first block address signal which is enabled when the first cell block is selected; and
a second logic element configured to perform a logic operation on an output signal of the first logic element, a first block repair signal which is enabled when the defect occurs in the first cell block, and a second block address signal which is enabled when the second cell block is selected.

8. The block isolation control circuit of claim 6, wherein the second control signal generation unit comprises:
a first logic element configured to perform a logic operation on a test mode signal for entry into the test mode and an inversion signal of a second block address signal which is enabled when the second cell block is selected; and
a second logic element configured to perform a logic operation on an output signal of the first logic element, a second block repair signal which is enabled when the defect occurs in the second cell block, and a first block address signal which is enabled when the first cell block is selected.

9. The block isolation control circuit of claim 6, further comprising:
a first block repair fuse unit configured to generate a first block repair signal which is enabled when the defect occurs in the first cell block; and
a second block repair fuse unit configured to generate a second block repair signal which is enabled when the defect occurs in the second cell block.

10. The block isolation control circuit of claim 9, wherein the first block repair fuse unit comprises:
a pull up element configured to pull up an output node in response to a power-up signal;
a pull down element configured to pull down the output node in response to the power-up signal;
a fuse connected between the pull up element and the output node and configured to be cut when the defect occurs in the first cell block; and
a latch unit configured to latch a signal of the output node.

11. The block isolation control circuit of claim 9, wherein the second block repair fuse unit comprises:
a pull up element configured to pull up an output node in response to a power-up signal;
a pull down element configured to pull down the output node in response to the power-up signal;
a fuse connected between the pull up element and the output node and configured to be cut when the defect occurs in the second cell block; and
a latch unit configured to latch a signal of the output node.

12. A block isolation control circuit, comprising:
a block repair selector configured to generate a repair detection signal which is enabled when a defect occurs in a cell block, the cell block is replaced with a first redundant cell block, and the cell block is selected;
a control signal generation unit configured to generate a control y|gnu| which is disabled when a defect occurs in the first redundant cell block and it is necessary to replace the first redundant cell block with a second redundant cell block, or when the first redundant cell block is not selected in a test mode; and
at least one switch element connected between the first redundant cell block and a bit line sense amplifier,
wherein the switch element isolates the first redundant cell block from the bit line sense amplifier when the control signal is disabled.

13. The block isolation control circuit of claim 12, wherein the block repair selector comprises:
a pull up element configured to pull up an output node in response to a precharge signal;
a fuse connected to the output node; and
a pull down element connected between the output node and a ground voltage terminal and configured to be turned on when the cell block is selected.

14. The block isolation control circuit of claim 13, wherein the fuse is not cut when the defect occurs in the cell block and the cell block is replaced with the first redundant cell block.

15. The block isolation control circuit of claim 12, wherein the control signal generation unit comprises:
a first logic element configured to perform a logic operation on a test mode signal for entry into the test mode and the repair detection signal; and
a second logic element configured to perform a logic operation on an output signal of the first logic element and a block repair signal which is enabled when the defect occurs in the first redundant cell block.

16. The block isolation control circuit of claim 12, further comprising a block repair fuse unit configured to generate a block repair signal which is enabled when the defect occurs in the first redundant cell block.

17. The block isolation control circuit of claim 16, wherein the block repair fuse unit comprises:
a pull up element configured to pull up an output node in response to a power up signal;
a pull down element configured to pull down the output node in response to the power up signal;
a fuse connected between the pull up element and the output node; and
a latch unit configured to latch a signal of the output node.

18. The block isolation control circuit of claim 17, wherein the fuse is cut when the defect occurs in the first redundant cell block.
